(19) United States
(12) Patent Application Publication
(10) Pub. No.: US 2025/0081446 A1
(43) Pub. Date: Mar. 6, 2025

(54) SEMICONDUCTOR STRUCTURE AND MANUFACTURING METHOD THEREOF

(71) Applicant: CXMT Corporation, Hefei City (CN)

(72) Inventor: Dongqi LI, Hefei City (CN)

(73) Assignee: CXMT Corporation, Hefei City (CN)

(21) Appl. No.: 18/950,142

(22) Filed: Nov. 17, 2024

Related U.S. Application Data
(63) Continuation of application No. PCT/CN2024/086405, filed on Apr. 7, 2024.

(30) Foreign Application Priority Data
Apr. 26, 2023 (CN) 202310466013.7

(51) Int. Cl. H10B 12/00

(52) U.S. Cl. CPC H10B 12/485; H10B 12/0335

(57) ABSTRACT

A semiconductor structure and a manufacturing method thereof are provided. The method for manufacturing the semiconductor structure includes: forming a plurality of mask patterns arranged in an array and spaced apart on a base substrate; forming a first conductive layer on sidewalls of the mask patterns; and forming a second conductive layer in filling holes. The first conductive layer on the sidewalls of two mask patterns adjacent to each other in adjacent rows is in contact, and the first conductive layer on the sidewalls of two mask patterns adjacent to each other in a same row and two mask patterns opposite each other in alternate rows encloses to form one of filling holes; a doping concentration of the second conductive layer is greater than a doping concentration of the first conductive layer.

### CROSS-REFERENCE TO RELATED APPLICATIONS

This is a continuation of International Patent Application No. PCT/CN2024/086405 filed on Apr. 7, 2024, which claims priority to Chinese Patent Application No. 202310466013.7 filed on Apr. 26, 2023. The disclosures of the above-referenced applications are hereby incorporated by reference in their entirety.

### BACKGROUND

A dynamic random access memory (DRAM) is a commonly used semiconductor structure in electronic devices such as computers, which includes a plurality of memory cells, each memory cell typically including a transistor and a capacitor. A gate of the transistor is electrically connected to a word line (WL), a source of the transistor is electrically connected to a bit line (BL), and a drain of the transistor is electrically connected to the capacitor. The word line voltage on the word line can control the on and off of the transistor, such that data information stored in the capacitor can be read or the data information can be written to the capacitor through the bit line.

However, as the dimension's shrink, a bit line contact structure (BLC) in contact with a source usually has a void or a gap, leading to poor transmission performance of a semiconductor structure.

### SUMMARY

In view of the above problem, embodiments of the present disclosure provide a semiconductor structure and a manufacturing method thereof.

The present disclosure relates to the field of semiconductor technologies, and in particular, to a semiconductor structure and a manufacturing method thereof.

According to some embodiments, a first aspect of the present disclosure provides a method for manufacturing a semiconductor structure. The method includes: providing a base substrate, where the base substrate is provided with a plurality of active areas spaced apart from each other; forming a plurality of mask patterns arranged in an array and spaced apart on the base substrate, where the plurality of mask patterns cover end parts of the plurality of active areas, and the end parts of two of the plurality of active areas adjacent to each other along a first direction share one of the plurality of mask patterns; in any three adjacent rows of the plurality of mask patterns, mask patterns in a same row are arranged along a second direction, mask patterns in adjacent rows are offset, and mask patterns in alternate rows are oppositely arranged; a first distance between two of the plurality of mask patterns adjacent to each other in a same row and a second distance between two of the plurality of mask patterns opposite each other in alternate rows are both greater than a third distance between two of the plurality of mask patterns adjacent to each other in adjacent rows; the second direction intersects with the first direction; forming a first conductive layer on sidewalls of the plurality of mask patterns, where the first conductive layer on the sidewalls of two of the plurality of mask patterns adjacent to each other in adjacent rows is in contact, and the first conductive layer on the sidewalls of two of the plurality of mask patterns adjacent to each other in a same row and two of the plurality of mask patterns opposite each other in alternate rows encloses to form one of filling holes; and forming a second conductive layer in the filling holes, with a doping concentration of the second conductive layer greater than a doping concentration of the first conductive layer.

According to some embodiments, a second aspect of the present disclosure provides a semiconductor structure. The semiconductor structure includes: a base substrate, where the base substrate is provided with a plurality of active areas spaced apart from each other; a plurality of mask patterns arranged in an array and spaced apart on the base substrate, where the plurality of mask patterns cover end parts of the plurality of active areas, and the end parts of two of the plurality of active areas adjacent to each other along a first direction share one of the plurality of mask patterns; in any three adjacent rows of the plurality of mask patterns, mask patterns in a same row are arranged along a second direction, mask patterns in adjacent rows are offset, and mask patterns in alternate rows are oppositely arranged; a first distance between two of the plurality of mask patterns adjacent to each other in a same row and a second distance between two of the plurality of mask patterns opposite each other in alternate rows are both greater than a third distance between two of the plurality of mask patterns adjacent to each other in adjacent rows; the second direction intersects with the first direction; and bit line contact structures in contact with the plurality of active areas, each of the bit line contact structures including a first contact layer and a second contact layer, where the first contact layer is connected on two opposing sides of each one of the plurality of mask patterns along the first direction, and a thickness of the first contact layer is greater than one-half of the third distance and less than one-half of the second distance; the second contact layer is located between two first contact layers adjacent to each other along the first direction, and a doping concentration of the second contact layer is greater than a doping concentration of the first contact layers.

### BRIEF DESCRIPTION OF THE DRAWINGS

FIG. 1 is a schematic diagram of a structure after forming a mask pattern in the related technology;

FIG. 2 is a cross-sectional schematic diagram showing location A in FIG. 1;

FIG. 3 is a cross-sectional schematic diagram showing location B in FIG. 1;

FIG. 4 is a schematic diagram of a structure after forming a first conductive layer in the related technology;

FIG. 5 is a cross-sectional schematic diagram showing location A in FIG. 4;

FIG. 6 is a cross-sectional schematic diagram showing location B in FIG. 4;

FIG. 7 is a schematic diagram of a structure at cross-section A after forming a second conductive layer in the related technology;

FIG. 8 is a schematic diagram of a structure at cross-section B after forming a second conductive layer in the related technology;

FIG. 9 is a schematic diagram of a structure after removing a portion of the first conductive layer and the second conductive layer in the related technology;

FIG. 10 is a cross-sectional schematic diagram showing location A in FIG. 9;

FIG. 11 is a cross-sectional schematic diagram showing location B in FIG. 9;

FIG. 12 is a flow chart of a method of manufacturing a semiconductor structure according to an embodiment of the present disclosure;

FIG. 13 is a schematic diagram of a structure after forming a mask pattern according to an embodiment of the present disclosure;

FIG. 14 is a cross-sectional schematic diagram showing location A in FIG. 13;

FIG. 15 is a schematic diagram of a structure after forming a contact groove according to an embodiment of the present disclosure;

FIG. 16 is a schematic diagram of forming a pattern unit according to an embodiment of the present disclosure;

FIG. 17 is another schematic diagram of forming a pattern unit according to an embodiment of the present disclosure;

FIG. 18 is still another schematic diagram of forming a pattern unit according to an embodiment of the present disclosure;

FIG. 19 is a schematic diagram of a structure after forming a first conductive layer according to an embodiment of the present disclosure;

FIG. 20 is a cross-sectional schematic diagram showing location A in FIG. 19;

FIG. 21 is a cross-sectional schematic diagram showing location B in FIG. 19;

FIG. 22 is a schematic diagram of a structure after removing a first conductive layer at the bottom of a filling hole according to an embodiment of the present disclosure;

FIG. 23 is a cross-sectional schematic diagram showing location A in FIG. 22;

FIG. 24 is a cross-sectional schematic diagram of a structure after forming a second conductive layer according to an embodiment of the present disclosure;

FIG. 25 is another cross-sectional schematic diagram of the structure after forming a second conductive layer according to an embodiment of the present disclosure;

FIG. 26 is a schematic diagram of another structure after forming a second conductive layer according to an embodiment of the present disclosure;

FIG. 27 is a top view after removing a portion of the mask pattern according to an embodiment of the present disclosure;

FIG. 28 is a cross-sectional schematic diagram showing location A in FIG. 27;

FIG. 29 is another cross-sectional schematic diagram showing location A in FIG. 27;

FIG. 30 is a schematic diagram of a structure after forming a bit line according to an embodiment of the present disclosure;

FIG. 31 is a schematic diagram of a structure at a cross-section parallel to a bit line according to an embodiment of the present disclosure; and

FIG. 32 is a schematic diagram of positions of a first contact layer and a second contact layer according to an embodiment of the present disclosure.

### REFERENCE NUMERALS IN THE FIGURES ARE AS FOLLOWS

10: base substrate; 11: active area; 12: contact groove; 20: mask pattern; 21: second protective layer; 22: barrier layer; 23: third conductive layer; 24: first protective layer; 25: laminated structure; 26: connecting part; 30: first conductive layer; 31: filling hole; 32: first contact layer; 40: second conductive layer; 41: void; 42: second contact layer; 50: bit line; 51: metal layer; 52: cap layer; 60: word line; and 70: pattern unit.

### DETAILED DESCRIPTION

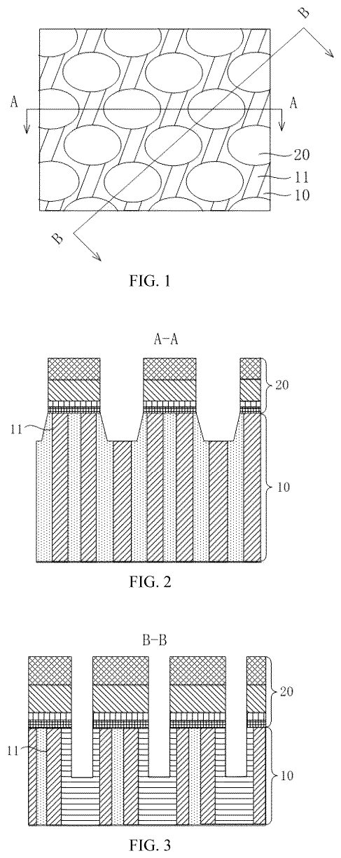

There is a problem of poor transmission performance in semiconductor structures in the related technology, which the inventor has conducted research on. With reference to FIGS. 1 to 3, during the manufacturing of a semiconductor structure, an array of mask patterns 20 is formed on a base substrate 10. Mask patterns 20 in adjacent rows are offset, and a bit line contact structure formed subsequently is in contact with the middle of an active area. Mask patterns 20 in adjacent rows are offset, which causes both a first distance between two mask patterns 20 adjacent to each other in the same row and a second distance between two mask patterns 20 opposite each other in alternate rows to be greater than a third distance between two mask patterns 20 adjacent to each other in adjacent rows, that is, a gap between two mask patterns 20 adjacent to each other in adjacent rows has a larger aspect ratio.

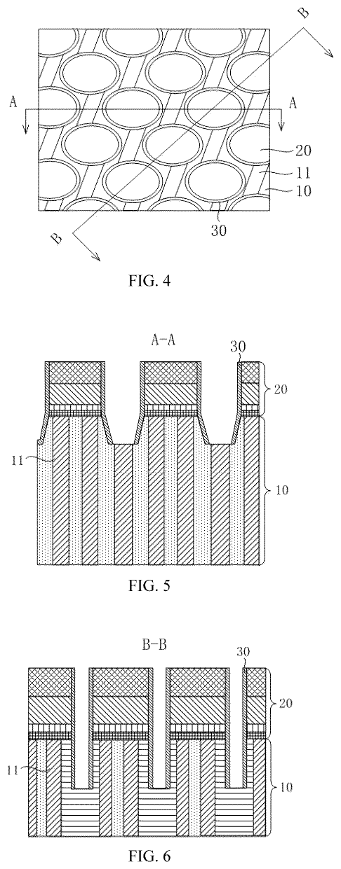

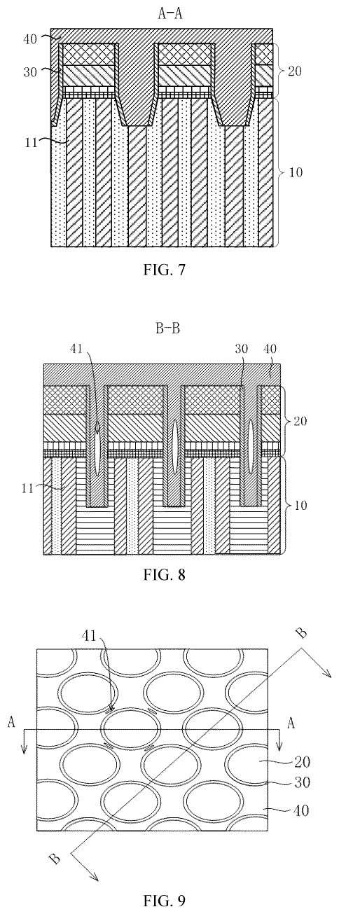

With reference to FIGS. 4 to 6, a first conductive layer 30 is formed on a sidewall of each mask pattern 20, and the material of the first conductive layer 30 is typically undoped polysilicon, which serves as a seed and is usually relatively thin. The first conductive layer 30 on the sidewalls of the mask patterns 20 is spaced apart, and an aspect ratio of a gap between the first conductive layer 30 on the sidewalls of two mask patterns 20 adjacent to each other in adjacent rows is further increased. With reference o FIGS. 7 and FIG. 8, a second conductive layer 40 is formed on a sidewall of the first conductive layer 30. A material of the second conductive layer 40 is typically heavily doped polysilicon (for example, N-type polysilicon) for reducing the contact resistance between the second conductive layer 40 and active area 11 of the base substrate 10. The second conductive layer 40 is formed by nucleating and epitaxially growing on the first conductive layer 30, such that the second conductive layer 40 can inherit a crystal structure of the seed to ensure relatively high crystallinity of the second conductive layer 40.

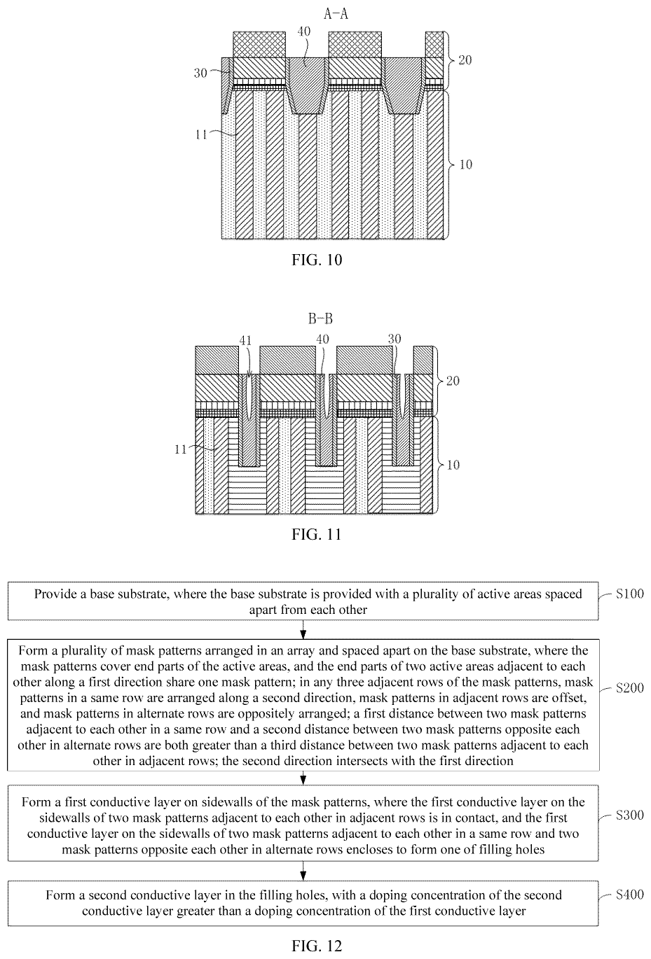

However, heavily doped polysilicon is of a poor filling capability, and usually cannot completely fill up a gap with a high aspect ratio. With reference to FIGS. 9 to 11, there are a large number of voids 41 between the sidewalls of two mask patterns 20 adjacent to each other in adjacent rows, affecting the structure for subsequent bit line deposition and etching process, easily causing a short circuit between a bit line and a capacitor contact structure, and thus affecting the transmission performance of the semiconductor structure.

Therefore, the embodiments of the present disclosure provide a method for manufacturing a semiconductor structure. A first conductive layer is formed on the sidewalls of the mask patterns, and the first conductive layer is filled between two mask patterns adjacent to each other in adjacent rows; Moreover, the first conductive layer on the sidewalls of two mask patterns adjacent to each other in the same row and two mask patterns opposite each other in alternate rows encloses to form a filling hole, and a second conductive layer is formed in the filling holes. The doping concentration of the second conductive layer is greater than that of the first conductive layer. The first conductive layer with a lower doping concentration is of a better filling capability and can fill up the space between mask patterns adjacent to each other in adjacent rows, leaving few or even no voids, thereby ensuring the insulating isolation between the bit line and the capacitor contact structure, and thus ensuring the transmission performance of the semiconductor structure. The second conductive layer with a higher doping concentration can reduce the contact resistance between the second conductive layer and the active area, thereby also ensuring the transmission performance of the semiconductor structure.

To make the above objectives, features, and advantages of the embodiments of the present disclosure clearer and more comprehensible, the technical solutions in the embodiments of the present disclosure will be clearly and comprehensively described hereinafter with reference to the accompanying drawings of the embodiments of the present disclosure. It is evident that the described embodiments are only a portion of the embodiments of the present disclosure rather than all of the embodiments. Based on the embodiments of the present disclosure, all other embodiments obtained by those skilled in the art without creative work shall fall within the protection scope of the present disclosure.

With reference to FIG. 12, an embodiment of the present disclosure provides a method for manufacturing a semiconductor structure. The manufacturing method specifically includes the following steps.

In step S100, a base substrate is provided, where the base substrate is provided with a plurality of active areas spaced apart from each other.

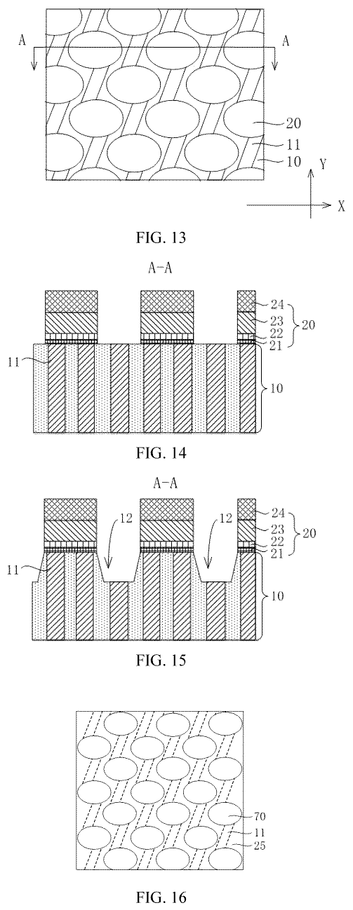

With reference to FIG. 13, a base substrate 10 provides support for structures (for example, bit line contact structures and bit lines) thereon, and a material of the base substrate 10 may be monocrystalline silicon, polysilicon, germanium, germanium-silicon, silicon on insulator (SOI), germanium on insulator (GOI), or other semiconductor materials. The base substrate 10 is provided with a plurality of active areas (AA) 11, and the plurality of active areas 11 are spaced apart. For example, the plurality of active areas 11 are separated by shallow trench isolation (STI) structures, and the active areas 11 are used to form the source region, the drain region, and the channel region of transistors.

In step S200, a plurality of mask patterns arranged in an array and spaced apart are formed on the base substrate, where the mask patterns cover end parts of the active areas, and the end parts of two active areas adjacent to each other along a first direction share one mask pattern. In any three adjacent rows of the mask patterns, mask patterns in the same row are arranged along a second direction, mask patterns in adjacent rows are offset, and mask patterns in alternate rows are oppositely arranged; a first distance between two mask patterns adjacent to each other in the same row and a second distance between two mask patterns opposite each other in alternate rows are both greater than a third distance between two mask patterns adjacent to each other in adjacent rows, and the second direction intersects with the first direction.

With reference to FIGS. 12 and 13, a plurality of mask patterns 20 are formed in a spaced-apart manner on the base substrate 10, and the plurality of mask patterns 20 are arranged in an array. Each mask pattern 20 covers the end part of the active area 11, and the end parts of two active areas 11 adjacent to each other along the first direction share one mask pattern 20. That is, the end parts of two adjacent active areas 11 along the first direction that are close to each other are covered by the same mask pattern 20, such that each mask pattern 20 covers at least the end part of one active area 11.

It can be understood that, each mask pattern 20 located on the inner side along the first direction among the plurality of mask patterns 20 covers the end parts of two active areas 11 adjacent to each other along the first direction. That is, mask patterns 20 located at both ends along the first direction cover the end parts of the active areas 11 on the outer side. In other words, two rows of mask patterns 20 located on both sides along the first direction correspondingly cover the end parts of the two rows of active areas 11 located on both sides distal to each other. For example, the first direction is a first horizontal direction, the uppermost row of the mask patterns 20 correspondingly covers the upper ends of the uppermost row of the active areas 11, and the lowermost row of the mask patterns 20 correspondingly covers the lower ends of the lowermost row of active areas 11.

As shown in FIG. 13, in any three adjacent rows of the mask patterns 20, mask patterns 20 in the same row are arranged along a second direction, mask patterns 20 in adjacent rows are offset, and mask patterns 20 in alternate rows are oppositely arranged. Projections of adjacent rows of mask patterns 20 in the first direction only partially overlap, and projections of alternate rows of mask patterns 20 in the first direction completely overlap. The mask patterns 20 opposite each other in alternate rows are arranged along the first direction to form one column. That is, the first direction is the column direction, the second direction is the row direction, and the first direction intersects with, for example, perpendicular to, the second direction. In addition, the mask patterns 20 are arranged in a hexagonal layout, with a row of mask patterns 20 between alternate rows of mask patterns 20 located along the central axis between the two alternate rows of mask patterns 20, and the mask patterns 20 at the central axis positions are located at the central position of four adjacent mask patterns 20 in adjacent rows, thereby increasing the density of the mask patterns 20 and improving the space utilization rate of the semiconductor structure. The first direction is the first horizontal direction (Y direction) as shown in FIG. 13, and the second direction is the second horizontal direction (X direction) as shown in FIG. 13. The angle between the direction of the line connecting two mask patterns 20 adjacent to each other in adjacent rows of mask patterns 20 and the first direction is 30° to 45°, or the angle between the direction of the line connecting two mask patterns 20 adjacent to each other in adjacent rows of mask patterns 20 and the second direction is 30° to 45°. For example, in the array formed by the plurality of mask patterns 20, in a square area with the same length in the first direction and the second direction, the number of columns is twice the number of mask patterns 20 per row. For example, if there are five mask patterns 20 per row, the plurality of mask patterns 20 form ten columns.

It should be noted that a plurality of word lines 60 spaced apart from each other are further arranged in the base substrate 10 (see FIGS. 31 and 32). The plurality of word lines 60 all extend along the second direction and all pass through the active areas 11. That is, the second direction is an extension direction of the word line 60. Both the first direction and the second direction intersect with the extension direction of the active areas 11.

There is a first distance between two mask patterns 20 adjacent to each other in the same row, a second distance between two mask patterns 20 opposite each other in alternate rows, and a third distance between two mask patterns 20 adjacent to each other in adjacent rows. Both the first distance and the second distance are greater than the third distance. As shown in FIG. 13, the distance between two adjacent mask patterns 20 in the second horizontal direction and the distance between two adjacent mask patterns 20 in the first horizontal direction are both greater than the distance between two adjacent mask patterns 20 in the diagonal direction.

It can be understood that, as mask patterns 20 in adjacent rows are offset, some rows (for example, the uppermost row or the lowermost row) of mask patterns 20 in the plurality of rows of mask patterns 20 have one adjacent row, and some of the mask patterns 20 in the rows (for example, mask patterns 20 located at both ends along the second direction) have one corresponding adjacent mask pattern 20 in their adjacent row, while other mask patterns 20 have two corresponding adjacent mask patterns 20 in their adjacent row. That is, some of the mask patterns 20 adjacent to each other in adjacent rows have one or two third distances. Some rows of mask patterns 20 in the plurality of rows of mask patterns 20 have two adjacent rows, and some of the mask patterns 20 in the rows have one corresponding adjacent mask pattern 20 in their adjacent rows, while other mask patterns 20 have two corresponding adjacent mask patterns 20 in their adjacent rows. That is, some of the mask patterns 20 adjacent to each other in adjacent rows have two or four third distances. There is at least one third distance. The one or more third distances are all less than the first distance and less than the second distance.

In some examples, the mask patterns 20 each include a support layer, a third conductive layer 23, and a first protective layer 24 that are stacked up in sequence. The support layer is located on the base substrate 10 and may be a laminate. For example, the support layer includes a second protective layer 21 disposed on the base substrate 10 and a barrier layer 22 disposed on the second protective layer 21. A material of the first protective layer 24 and the second protective layer 21 may be an oxide, for example, silicon oxide. A material of the barrier layer 22 may be a nitride, for example, silicon nitride. A material of the third conductive layer 23 may be polysilicon. The second protective layer 21 may be formed simultaneously with the shallow trench isolation structures of the active areas 11 in the base substrate 10. For example, the base substrate 10 is etched to form the active areas 11 and shallow trenches surrounding the active areas 11; an insulation material is deposited in the shallow trenches as well as on the active areas 11, the insulation material filled in the shallow trenches forms the shallow trench isolation structures, and the insulation material covering the active areas 11 and the shallow trench isolation structures forms the second protective layer 21, thereby reducing the oxidation on top surfaces of the active areas 11.

In some examples, referring to FIG. 15, after forming the plurality of mask patterns 20 arranged in an array and spaced apart on the base substrate 10 (step S200), the method further includes: etching the base substrate 10 by using the mask patterns 20 as a mask to form interconnected contact grooves 12, which expose the active areas 11. That is, protrusions corresponding to the mask patterns 20 and the contact grooves 12 surrounding the protrusions and interconnected as a whole are formed in the base substrate 10. This, on one hand, increases the exposed area of the active areas 11 and increases the contact area between the first conductive layer 30 and the active areas 11, thereby reducing the contact resistance between the first conductive layer 30 and the active areas 11; on the other hand, by removing a portion of the base substrate 10, the oxide or the like on the active areas 11 can also be removed, thus fully exposing the active layer. The contact grooves 12 are interconnected as a whole to facilitate subsequent filling and removal of the first conductive layer 30 and the second conductive layer 40.

In step S300, a first conductive layer is formed on the sidewalls of the mask patterns, where the first conductive layer on the sidewalls of two mask patterns adjacent to each other in adjacent rows is in contact, and the first conductive layer on the sidewalls of two mask patterns adjacent to each other in the same row and two mask patterns opposite each other in alternate rows encloses to form one of filling holes.

The first conductive layer covers the sidewalls of the mask patterns 20, and the first conductive layer is in contact with the base substrate 10. The mask patterns 20 cover the end parts of the active areas 11, and the middle portions of the active areas 11 are exposed, such that the first conductive layer is also in contact with the active areas 11. The first conductive layer may be formed through a deposition process, for example, chemical vapor deposition (CVD), physical vapor deposition (PVD), or atomic layer deposition (ALD).

The first conductive layer on the sidewalls of two mask patterns 20 adjacent to each other in adjacent rows is in contact, such that the first conductive layer is filled into a gap between the two mask patterns 20 adjacent to each other in the adjacent rows. The first conductive layer on the sidewalls of two mask patterns 20 adjacent to each other in the same row, together with the first conductive layer on the sidewalls of two mask patterns 20 opposite each other in alternate rows, enclose to form a filling hole, and the filling hole is opposite to the active area 11, that is, the filling hole is located right above the active area 11.

In some possible implementations, the thickness of the first conductive layer is greater than one-half of the third distance, less than one-half of the first distance, and less than one-half of the second distance. In such an arrangement, the first conductive layer on the sidewalls of two mask patterns 20 adjacent to each other in adjacent rows is in contact, the first conductive layer on the sidewalls of two mask patterns 20 adjacent to each other in the same row is spaced apart, and the first conductive layer on the sidewalls of two mask patterns 20 opposite each other in alternate rows is spaced apart.

It can be understood that the first conductive layer on the sidewalls of two mask patterns 20 adjacent to each other in adjacent rows will be removed in the subsequent process, and an insulation material will be filled between the sidewalls of two mask patterns 20 adjacent to each other in adjacent rows. That is, the first conductive layer at these places will not be involved in the final electrical conduction of the circuit, such that the contact between the first conductive layer on the sidewalls of two mask patterns 20 adjacent to each other in adjacent rows does not affect the electrical performance of the semiconductor structure.

In step S400, a second conductive layer is formed in the filling hole, with the doping concentration of the second conductive layer greater than the doping concentration of the first conductive layer.

The second conductive layer is filled into the filling holes 31 to level the filling holes 31. The doping concentration of the second conductive layer is greater than the doping concentration of the first conductive layer. For example, the second conductive layer is N-type doped, and the first conductive layer is undoped. In such an arrangement, on one hand, the gap between the sidewalls of two mask patterns 20 adjacent to each other in adjacent rows has a higher aspect ratio, and the first conductive layer has a lower doping concentration and a smaller lattice, making it less likely to nucleate during the deposition process, that is, there is a high filling capability when the seed grows, such that the gap between the sidewalls of two mask patterns 20 adjacent to each other in adjacent rows can be filled up properly, and the voids in the first conductive layer at the location can be reduced or even prevented, thereby avoiding destroying the first conductive layer and the film structure thereon, and thus avoiding affecting the etching morphology of the subsequently formed bit lines. This ensures the insulating isolation between the bit line and the capacitor contact structure, avoids short circuits between the bit line and the capacitor contact structure, and ensures the transmission performance of the semiconductor structure. On the other hand, the higher doping concentration of the second conductive layer can reduce the contact resistance between the second conductive layer and the film in contact, thereby ensuring the transmission performance of the semiconductor structure.

In some examples, the first conductive layer and the second conductive layer are made of the same material, for example, polysilicon. That is, the first conductive layer is an undoped polysilicon layer, and the second conductive layer is an N-type doped polysilicon layer. In such an arrangement, while ensuring the filling capacity of the first conductive layer and the transmission performance of the second conductive layer, using the same material can further ensure that the first conductive layer and the second conductive layer have the same etching rate, which facilitates the control of the final bit line contact structure and the structure of the bit line.

In conclusion, in the method for manufacturing a semiconductor structure according to the embodiments of the present disclosure, the mask patterns 20 are formed on the base substrate 10, and the first conductive layer is formed on the sidewalls of the mask patterns 20, where the first conductive layer is filled between two mask patterns 20 adjacent to each other in adjacent rows. Moreover, the first conductive layer on the sidewalls of two mask patterns 20 adjacent to each other in the same row and two mask patterns 20 opposite each other in alternate rows encloses to form a filling hole 31, and the second conductive layer is formed in the filling holes 31, with the doping concentration of the second conductive layer greater than the doping concentration of the first conductive layer. The first conductive layer has a lower doping concentration, and there is a high filling capability when the seed grows, such that the gap between the sidewalls of two mask patterns 20 adjacent to each other in adjacent rows can be filled up properly, and the voids in the first conductive layer at the location can be reduced or even prevented, thereby avoiding destroying the first conductive layer and the film structure thereon, and thus avoiding affecting the etching morphology of the subsequently formed bit lines. This ensures the insulating isolation between the bit line and the capacitor contact structure, avoids short circuits between the bit line and the capacitor contact structure, and ensures the transmission performance of the semiconductor structure. The higher doping concentration of the second conductive layer can reduce the contact resistance between the second conductive layer and the active area 11, thereby ensuring the transmission performance of the semiconductor structure.

In some possible examples, referring to FIGS. 16 to 18, forming the plurality of mask patterns arranged in an array and spaced apart on the base substrate (step S200) includes: forming a laminated structure 25 on the base substrate; forming a mask layer on the laminated structure 25, where the mask layer is provided with a preset pattern; and etching the laminated structure 25 by using the mask layer as a mask, with the remaining laminated structure 25 forming the mask patterns.

The laminated structure 25 covers the top surface of the base substrate 10. The mask layer is located on the top surface of the laminated structure 25 and is provided with a preset pattern, exposing portions of the top surface of the laminated structure 25. The laminated structure 25 is etched by using the mask layer as a mask, and the portions of the laminated structure 25 not covered by the mask layer are removed, with the remaining laminated structure 25 forming the mask patterns 20.

The mask layer includes a plurality of pattern units 70 arranged in an array and spaced apart. The pattern units 70 correspond to the end parts of the active areas 11, and the end parts of two active areas 11 adjacent to each other along the first direction correspond to one pattern unit 70. The pattern unit 70 is in one-to-one correspondence with the mask pattern 20. In any three adjacent rows of the pattern units 70, pattern units 70 in the same row are arranged along the second direction, pattern units 70 in adjacent rows are offset, and pattern units 70 in alternate rows are oppositely arranged; a fourth distance between two pattern units 70 adjacent to each other in the same row and a fifth distance between two pattern units 70 opposite each other in alternate rows are both greater than a sixth distance between two pattern units 70 adjacent to each other in adjacent rows. The mask layer is formed through at least one patterning process.

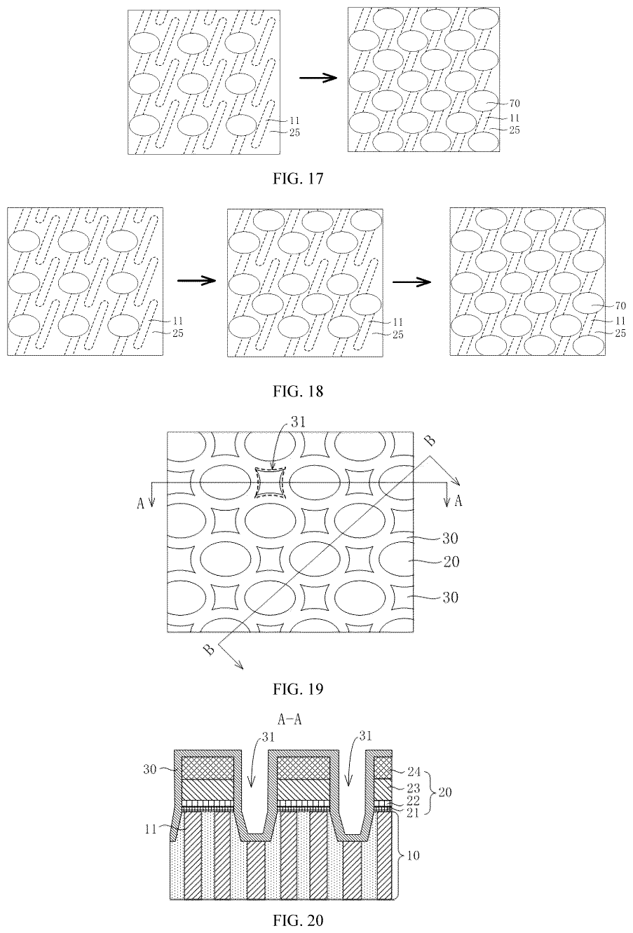

For example, referring to FIG. 16, the mask layer is formed through a single patterning process. That is, all the pattern units 70 are formed through a single patterning process to reduce the steps for manufacturing the mask layer. For another example, referring to FIG. 17, the mask layer is formed through two patterning processes. Pattern units 70 arranged in alternate rows are classified into one group, and all the pattern units 70 are classified into two groups. The two groups of pattern units 70 are each formed through a single patterning process. That is, pattern units 70 in even-numbered rows are formed through a single patterning process, and pattern units 70 in odd-numbered rows are formed through a single patterning process. For still another example, referring to FIG. 18, the mask layer is formed through three patterning processes. Pattern units 70 in odd-numbered rows are classified into one group, and among pattern units 70 in even-numbered rows, pattern units 70 in alternate rows are classified into one group, such that the pattern units 70 in the even-numbered rows are classified into two groups. The three groups of pattern units 70 are each formed through a single patterning process. Alternatively, pattern units 70 in even-numbered rows are classified into one group, and among pattern units 70 in odd-numbered rows, pattern units 70 in alternate rows are classified into one group, such that the pattern units 70 in the odd-numbered rows are classified into two groups. The three groups of pattern units 70 are each formed through a single patterning process.

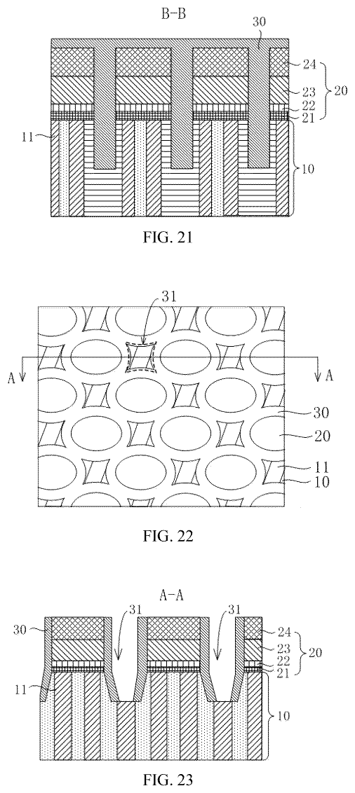

In some possible embodiments, referring to FIGS. 19 to 21, forming the first conductive layer 30 on the sidewalls of the mask patterns 20 (step S300) includes: depositing the first conductive layer 30 on the sidewalls and top surfaces of the mask patterns 20 as well as on the base substrate 10 exposed between the mask patterns 20. That is, the first conductive layer 30 covers the top surfaces and the sidewalls of the mask patterns 20, as well as the base substrate 10 exposed between the mask patterns 20, thus facilitating the formation of the first conductive layer 30.

Based on the above embodiments, in some possible examples, to reduce the contact resistance between the first conductive layer 30 and the second conductive layer 40 as well as the active area 11, after depositing the first conductive layer 30 on the sidewalls and the top surfaces of the mask patterns 20 as well as on the base substrate 10 exposed between the mask patterns 20, the method further includes: doping at least the first conductive layer 30 at the bottom of the filling holes 31. The fill hole 31 exposes the first conductive layer 30 on the active area 11. The first conductive layer 30 at the bottom of the filling hole 31 is not removed, and this portion of the first conductive layer 30 is doped to reduce the contact resistance between the first conductive layer 30 and the active area 11. The first conductive layer 30 is doped by an ion implantation process, and the direction of the ion implantation is tilted by a preset degree relative to the base substrate 10, such that the doping concentration of the first conductive layer 30 is relatively even.

Based on the above embodiments, in some other possible examples, referring to FIGS. 19, 20, 22, and 23, after the first conductive layer 30 covers the top surfaces and the sidewalls of the mask patterns 20, as well as the base substrate 10 exposed between the mask patterns 20, the method further includes: removing the first conductive layer 30 on the top surfaces of the mask patterns 20 as well as the first conductive layer 30 exposed within the filling holes 31 to expose the base substrate 10, thereby facilitating the subsequent formation of the second conductive layer 40 that contacts the active area 11 of the base substrate 10. For example, a portion of the first conductive layer 30 is removed by hydrofluoric acid (HF) wet etching, retaining the first conductive layer 30 on the sidewalls of the mask patterns 20. The filling hole 31 extends to the active area 11 to expose the active area 11.

While removing the first conductive layer 30 exposed within the filling holes 31, a portion of the base substrate 10 exposed within the filling holes 31 is also removed, forming recesses that expose the active areas 11. That is, the depth of the filling hole 31 is further increased, the base substrate 10 exposed within the filling hole 31 has a stepped shape relative to the base substrate 10 below the first conductive layer 30, and the base substrate 10 exposed within the filling hole 31 is recessed downward to expose the active area 11, thereby increasing the area of the exposed active area 11. The depth of the recess is 1 nm to 2 nm, and the shape of the recess is hemispherical or semi-ellipsoidal.

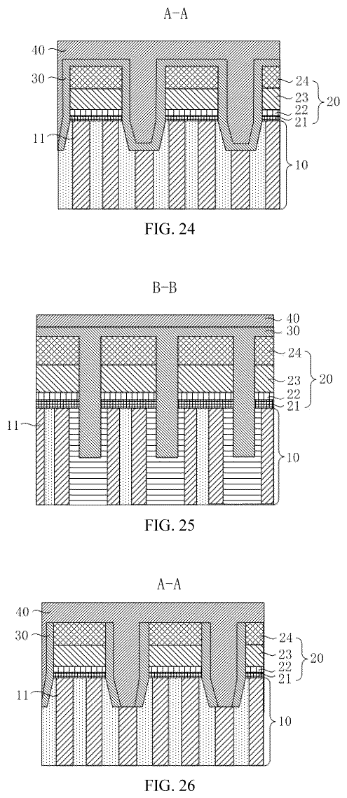

In some examples, referring to FIGS. 24 to 26, forming the second conductive layer 40 in the filling hole 31, with the doping concentration of the second conductive layer 40 greater than the doping concentration of the first conductive layer 30 (step S400), includes: depositing the second conductive layer 40 in the filling hole 31, on the mask pattern 20, and on the first conductive layer 30, with the second conductive layer 40 filling up the filling hole 31 and covering the top surface of the mask pattern 20 and the top surface of the first conductive layer 30.

In an example in which the fill hole 31 does not expose the active area 11, as shown in FIGS. 20, 21, 24, and 25, when the second conductive layer 40 is formed in the filling hole 31, the second conductive layer 40 fills up the filling hole 31 and covers the top surface of the first conductive layer 30. The second conductive layer 40 covers the first conductive layer 30, and the second conductive layer 40 does not contact the active area 11.

In an example in which the filling hole 31 exposes the active area 11, as shown in FIGS. 23 and 26, the second conductive layer 40 fills up the filling hole 31 and covers the top surface of the first conductive layer 30. The bottom surface of the second conductive layer 40 is in contact with the active area 11, and the side surfaces of the second conductive layer 40 are surrounded by the first conductive layer 30.

With reference to FIGS. 24 and 26, the mask pattern 20 includes a support layer, a third conductive layer 23, and a first protective layer 24 that are stacked up in sequence; after depositing the second conductive layer 40 in the filling hole 31, on the mask pattern 20, and on the first conductive layer 30, with the second conductive layer 40 filling up the filling hole 31 and covering the top surface of the mask pattern 20 and the top surface of the first conductive layer 30, the method further includes:
etching the second conductive layer 40, the first conductive layer 30, and the first protective layer 24 to expose the third conductive layer 23;
forming an initial bit line layer on the first conductive layer 30, the second conductive layer 40, and the third conductive layer 23; and
etching the initial bit line layer, the first conductive layer 30, the second conductive layer 40, and the third conductive layer 23, where the initial bit line layer forms a plurality of bit lines 50 that are spaced apart and extend along the first direction, the first conductive layer 30 forms a first contact layer 32, the second conductive layer 40 forms a second contact layer 42, and the third conductive layer 23 forms a connecting part 26; the first contact layer 32 is connected on two opposing sides of each connecting part 26 along the first direction and extends to the base substrate 10, and the second contact layer 42 is filled between two adjacent first contact layers 32 along the first direction.

As shown in FIGS. 24 and 26, the mask pattern 20 includes the support layer, the third conductive layer 23, and the first protective layer 24 that are stacked up in sequence. The support layer is located on the base substrate 10 and may be a laminate. For example, the support layer includes a second protective layer 21 disposed on the base substrate 10 and a barrier layer 22 disposed on the second protective layer 21. The third conductive layer 23, the first conductive layer 30, and the second conductive layer 40 may be made of the same material, for example, polysilicon, to reduce the interlayer separation between the third conductive layer 23, the first conductive layer 30, and the second conductive layer 40.

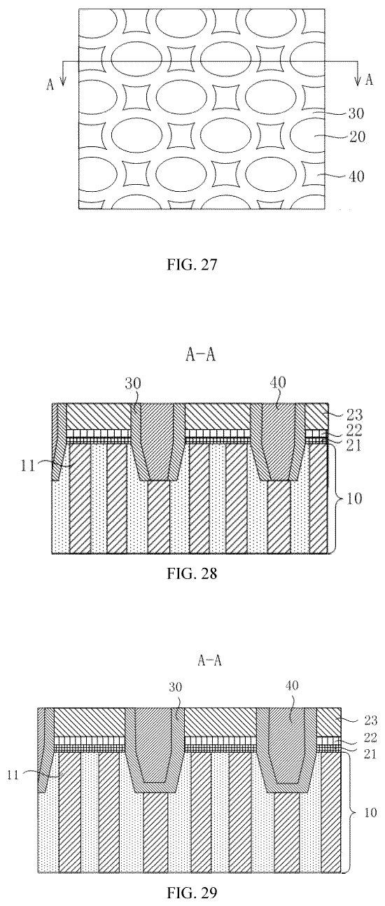

With reference to FIGS. 27 to 29, a portion of the second conductive layer 40, a portion of the first conductive layer 30, and the second protective layer 21 are removed by etching to expose the third conductive layer 23, and the top surface of the remaining second conductive layer 40 and the top surface of the remaining first conductive layer 30 are flush with the top surface of the third conductive layer 23. The initial bit line layer covers the remaining first conductive layer 30, the remaining second conductive layer 40, and the remaining third conductive layer 23. The initial bit line layer is a laminate including a metal layer 51 disposed on the second conductive layer 40 and a cap layer 52 disposed on the metal layer 51. The metal layer 51 may be a tungsten layer, a titanium nitride layer, or a laminate thereof, and the cap layer 52 may be a silicon nitride layer, a silicon oxynitride layer, a silicon carbonitride layer, or the like.

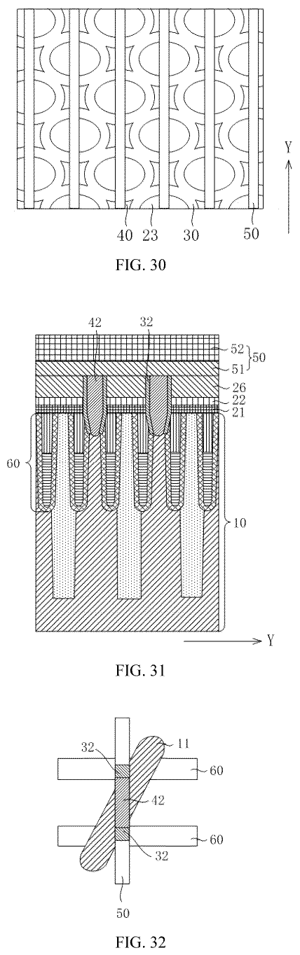

As shown in FIG. 30, the initial bit line layer is etched to form a plurality of bit lines 50. The first conductive layer 30, the second conductive layer 40, and the third conductive layer 23 are further etched. As shown in FIGS. 31 and 32, the first conductive layer 30 forms a plurality of first contact layers 32, the second conductive layer 40 forms a plurality of second contact layers 42, and the third conductive layer 23 forms connecting parts 26. The support layer below the third conductive layer 23 is not etched.

The plurality of bit lines 50 extend along the first direction and are spaced apart. Each bit line 50 corresponds to a plurality of second contact layers 42, a plurality of first contact layers 32, and a plurality of connecting parts 26, and the bit line 50, the second contact layers 42, the first contact layers 32, and the connecting parts 26 that correspond to each other are in contact. Along the first direction, one column of the first contact layers 32, the second contact layers 42, and the connecting parts 26 are connected into a whole, and the first contact layers 32, the second contact layers 42, and the connecting parts 26 are all located right below the corresponding bit line 50. The orthographic projection of the bit line 50 on the base substrate 10 covers the orthographic projection of the corresponding second contact layers 42 on the base substrate 10, covers the orthographic projection of the corresponding first contact layers 32 on the base substrate 10, and covers the orthographic projection of the corresponding connecting parts 26 on the base substrate 10.

The first contact layer 32 is connected on the two opposing sides of each connecting part 26 along the first direction and extends to the base substrate 10. That is, each connecting part 26 and the support layer below the connecting part 26 are provided with a first contact layer 32 on each of the two opposing sides in the first direction, with the corresponding first contact layer 32 correspondingly in contact with the sidewalls of the connecting part 26 and the support layer. The second contact layer 42 is filled between two first contact layers 32 adjacent to each other along the first direction, and the top surface of the first contact layer 32, the top surface of the second contact layer 42, and the top surface of the connecting part 26 are flush with each other.

The embodiments of the present disclosure further provide a semiconductor structure. Referring to FIGS. 15, 31, and 32, the semiconductor structure includes:
a base substrate 10, where the base substrate 10 is provided with a plurality of active areas 11 spaced apart from each other;
a plurality of mask patterns 20 arranged in an array and spaced apart on the base substrate 10, where the mask patterns 20 cover end parts of the active areas 11, and the end parts of two active areas 11 adjacent to each other along a first direction share one mask pattern 20; in any three adjacent rows of the mask patterns 20, mask patterns 20 in the same row are arranged along a second direction, mask patterns 20 in adjacent rows are offset, and mask patterns 20 in alternate rows are oppositely arranged; a first distance between two mask patterns 20 adjacent to each other in the same row and a second distance between two mask patterns 20 opposite each other in alternate rows are both greater than a third distance between two mask patterns 20 adjacent to each other in adjacent rows; the second direction intersects with the first direction; and
bit line contact structures in contact with the active areas 11, each bit line contact structure including a first contact layer and a second contact layer, where the first contact layer is connected on the two opposing sides of each mask pattern 20 along the first direction, and the thickness of the first contact layer is greater than one-half of the third distance and less than one-half of the second distance; the second contact layer is located between two first contact layers adjacent to each other along the first direction, and the doping concentration of the second contact layer is greater than the doping concentration of the first contact layer.

The base substrate 10 may be a silicon base substrate, a germanium base substrate, a silicon on insulator base substrate, a germanium on insulator base substrate, or the like. The base substrate 10 is provided with a plurality of active areas 11, the plurality of active areas 11 are spaced apart, and the top surfaces of the plurality of active areas 11 are exposed. The base substrate 10 further includes shallow trench isolation structures, and the shallow trench isolation structures isolate the active areas 11 from each other. The base substrate 10 is provided with a plurality of mask patterns 20 spaced apart from each other, and the plurality of mask patterns 20 are arranged in an array. Each mask pattern 20 covers the end part of the active area 11, and the end parts of two adjacent active areas 11 along the first direction that are close to each other are covered by the same mask pattern 20, such that each mask pattern 20 covers at least one end part of an active area 11.

In any three adjacent rows of the mask patterns 20, mask patterns 20 in the same row are arranged along a second direction, mask patterns 20 in adjacent rows are offset, and mask patterns 20 in alternate rows are oppositely arranged. The mask patterns 20 opposite each other in alternate rows are arranged along the first direction to form one column. That is, the first direction is the column direction, the second direction is the row direction, and the first direction intersects with, for example, perpendicular to, the second direction to increase the density of the mask patterns 20 and improve the space utilization rate of the semiconductor structure. There is a first distance between two mask patterns 20 adjacent to each other in the same row, a second distance between two mask patterns 20 opposite each other in alternate rows, and a third distance between two mask patterns 20 adjacent to each other in adjacent rows. The third distance is less than the second distance.

It can be understood that some of the mask patterns 20 have one adjacent mask pattern 20 in an adjacent row, while another part of the mask patterns 20 have two adjacent mask patterns 20 in adjacent rows, and the last part of the mask patterns 20 have four adjacent mask patterns 20 in adjacent rows. That is, there are one or more third distances between two mask patterns 20 adjacent to each other in adjacent rows, and the third distances are all less than the second distance.

The bit line contact structure is located on the base substrate 10 and in contact with the active areas 11 of the base substrate 10. The bit line contact structure is connected between two mask patterns 20 adjacent to each other along the first direction, thus connecting a column of mask patterns 20 opposite each other in alternate rows to provide support for the structure thereon. The bit line contact structure and the mask patterns 20 in the row adjacent to the mask patterns 20 connected to the bit line contact are also spaced apart. That is, the bit line contact structure is connected to a corresponding column of mask patterns 20 and is spaced from the mask patterns 20 in the adjacent column, such that each column of mask patterns 20 corresponds to one bit line 50.

In some examples, the bit line contact structure includes a first contact layer 32 and a second contact layer 42. The first contact layer 32 is connected on two opposing sides of each mask pattern 20 along the first direction. That is, each mask pattern 20 is provided with a first contact layer 32 on each of the two opposing sides along the first direction, and a corresponding first contact layer 32 is correspondingly in contact with the sidewall of the mask pattern 20. The mask pattern 20 includes a support layer on the base substrate 10 and a connecting part 26 on the support layer. The support layer may be a circular truncated cone or an elliptical truncated cone. The connecting part 26 may be a strip along the first direction, with its width matching the width of the first contact layer 32, and the two opposing sidewalls of the connecting part 26 along the first direction are aligned with the sidewalls of the support layer. The connecting part 26 and the support layer below the connecting part are correspondingly in contact with the sidewalls of the first contact layer 32.

The thickness of the first contact layer 32 is greater than one-half of the third distance and less than one-half of the second distance. This ensures that the first contact layer 32 has the required thickness and there is still a gap between the opposing first contact layers 32 of two adjacent mask patterns 20 in alternate rows. The second contact layer 42 is located between two first contact layers 32 adjacent to each other along the first direction. That is, each of the two sides of the second contact layer 42 along the first direction is provided with a first contact layer 32, and the second contact layer 42 is correspondingly in contact with the sidewalls of first contact layers 32 on the two sides. The top surface of the second contact layer 42 and the top surface of the first contact layer 32 are flush with the top surface of the mask pattern 20.

The doping concentration of the second contact layer 42 is higher than the doping concentration of the first contact layer 32. For example, the second contact layer 42 is N-type doped, and the first contact layer 32 is undoped. The first contact layer 32 has a lower doping concentration, which enhances its gap-filling capability, such that the voids in the first contact layer 32 can be reduced or even prevented to ensure the film structure thereon. The second contact layer 42 has a higher doping concentration, resulting in lower contact resistance between the second contact layer and the active area 11, which can ensure the transmission performance between the bit line contact structure and the active area 11.

Materials of the first contact layer 32 and the second contact layer 42 may be the same to facilitate the formation of the first contact layer 32 and the second contact layer 42. For example, the materials of the first contact layer 32 and the second contact layer 42 may both be polysilicon. For example, the first contact layer 32 includes an undoped polysilicon layer, and the second contact layer 42 includes an N-type doped polysilicon layer. The undoped polysilicon layer may have a higher filling capability during seed growth, such that there may be a few or no voids inside the first contact layers 32.

In some examples, the bottom surface of the first contact layer 32 and the bottom surface of the second contact layer 42 are both lower than the top surface of the base substrate 10, and the first contact layer 32 and the second contact layer 42 are both in contact with the active area 11. For example, the base substrate 10 exposed between the mask patterns 20 is provided with interconnected grooves, with the active area 11 exposed within the grooves. The first contact layer 32 and the second contact layer 42 are located at the bottom of the groove and are both in contact with the active area 11. The surface of the base substrate 10 in contact with the mask pattern 20 is the top surface of the base substrate 10, the bottom surface of the first contact layer 32 is lower than the top surface of the base substrate 10, and the bottom surface of the second contact layer 42 is lower than the top surface of the base substrate 10. The bottom surface of the second contact layer 42 may be lower than the bottom surface of the first contact layer 32. For example, the base substrate 10 exposed between the first contact layers 32 forms a recess, and the second contact layer 42 is located at the bottom of the recess. That is, the second contact layer 42 extends into the base substrate 10 to increase the contact area between the second contact layer 42 and the active area 11.

As shown in FIG. 32, the semiconductor structure further includes: a plurality of bit lines 50 that are spaced apart and extend along the first direction, each one of the plurality of bit lines 50 is correspondingly in contact with a column of bit line contact structures arranged along the first direction, and each one of the plurality of bit lines 50 is correspondingly in contact with a column of mask patterns 20 opposite each other in alternate rows.

Along the first direction, the bit line 50 is correspondingly disposed on the second contact layer 42, the first contact layer 32, and the mask pattern 20 in one column, and the orthographic projection of the bit line 50 on the base substrate 10 covers the orthographic projection of the corresponding second contact layer 42 on the base substrate 10 and covers the orthographic projection of the corresponding first contact layer 32 on the base substrate 10. The bit line 50 may include a metal layer 51 disposed on the second contact layer 42 and a cap layer 52 disposed on the metal layer 51. The metal layer 51 may be a tungsten layer, a titanium nitride layer, or a laminate thereof, and the cap layer 52 may be a silicon nitride layer, a silicon oxynitride layer, a silicon carbonitride layer, or the like.

In conclusion, the semiconductor structure in the embodiments of the present disclosure includes a base substrate 10, a plurality of mask patterns 20 arranged on the base substrate 10, and a bit line contact structure in contact with the active area 11 of the base substrate 10. The first distance between two mask patterns 20 adjacent to each other in the same row and the second distance between two mask patterns 20 opposite each other in alternate rows are both greater than the third distance between two mask patterns 20 adjacent to each other in adjacent rows. The bit line contact structure includes a first contact layer 32 and a second contact layer 42. The first contact layer 32 is connected on the two opposing sides of each mask pattern 20 along the first direction, and the thickness of the first contact layer 32 is greater than one-half of the third distance and less than one- half of the second distance. This ensures that the first contact layer 32 has the required thickness and there is still a gap between the opposing first contact layers 32 of two adjacent mask patterns 20. The second contact layer 42 is connected between two first contact layers 32 adjacent to each other along the first direction, and the doping concentration of the second contact layer 42 is greater than the doping concentration of the first contact layer 32. The first contact layer 32 has a lower doping concentration, which enhances its gap-filling capability, such that the voids in the first contact layer 32 can be reduced or even prevented to ensure the film structure thereon. The second contact layer 42 has a higher doping concentration, resulting in lower contact resistance between the second contact layer and the active area 11, which can ensure the transmission performance between the bit line contact structure and the active area 11.

In this specification, each embodiment or implementation is described in a progressive manner, and each embodiment focuses on the differences from other embodiments. The similar or identical parts between the embodiments can be referred to interchangeably. The reference terms such as “an embodiment”, “some embodiments”, “illustrative embodiments”, “example”, “specific example”, or “some examples” mean that the specific feature, structure, material, or characteristic described in conjunction with the embodiment or example is included in at least one embodiment or example of the present disclosure. In this specification, the illustrative description of the above terms does not necessarily refer to the same embodiment or example. Moreover, the specific feature, structure, material, or characteristic described may be combined in a suitable manner in any one or more embodiments or examples.

Finally, it should be noted that the above embodiments are merely used to illustrate the technical solutions of the present disclosure, rather than limiting them. Although the present disclosure has been described in detail with reference to the above embodiments, those of ordinary skill in the art should understand that they can still make modifications to the technical solutions described in the above embodiments or make equivalent replacements for some or all of the technical features. These modifications or replacements do not cause the essence of the corresponding technical solutions to depart from the scope of the technical solutions of the embodiments of the present disclosure.

What is claimed is:

1. A method for manufacturing a semiconductor structure, comprising:
providing a base substrate, wherein the base substrate is provided with a plurality of active areas spaced apart from each other;
forming a plurality of mask patterns arranged in an array and spaced apart on the base substrate, wherein the plurality of mask patterns cover end parts of the plurality of active areas, and the end parts of two of the plurality of active areas adjacent to each other along a first direction share one of the plurality of mask patterns; in any three adjacent rows of the plurality of mask patterns, mask patterns in a same row are arranged along a second direction, mask patterns in adjacent rows are offset, and mask patterns in alternate rows are oppositely arranged; a first distance between two of the plurality of mask patterns adjacent to each other in a same row and a second distance between two of the plurality of mask patterns opposite each other in alternate rows are both greater than a third distance between two of the plurality of mask patterns adjacent to each other in adjacent rows; the second direction intersects with the first direction;
forming a first conductive layer on sidewalls of the plurality of mask patterns, wherein the first conductive layer on the sidewalls of two of the plurality of mask patterns adjacent to each other in adjacent rows is in contact, and the first conductive layer on the sidewalls of two of the plurality of mask patterns adjacent to each other in a same row and two of the plurality of mask patterns opposite each other in alternate rows encloses to form one of filling holes; and
forming a second conductive layer in the filling holes, with a doping concentration of the second conductive layer greater than a doping concentration of the first conductive layer.

2. The method of claim 1, wherein after forming the plurality of mask patterns arranged in an array and spaced apart on the base substrate, the method further comprises:
etching the base substrate by using the plurality of mask patterns as a mask to form interconnected contact grooves, the contact grooves exposing the plurality of active areas.

3. The method of claim 2, wherein forming the first conductive layer on the sidewalls of the plurality of mask patterns comprises:
depositing the first conductive layer on the sidewalls and top surfaces of the plurality of mask patterns as well as on the base substrate exposed between the plurality of mask patterns.

4. The method of claim 3, wherein after depositing the first conductive layer on the sidewalls and the top surfaces of the plurality of mask patterns as well as on the base substrate exposed between the plurality of mask patterns, the method further comprises:
doping at least the first conductive layer at a bottom of the filling holes.

5. The method of claim 4, wherein the first conductive layer is doped by an ion implantation process, and a direction of the ion implantation is tilted by a preset degree relative to the base substrate.

6. The method of claim 3, wherein after depositing the first conductive layer on the sidewalls and the top surfaces of the plurality of mask patterns as well as on the base substrate exposed between the plurality of mask patterns, the method further comprises:
removing the first conductive layer on the top surfaces of the plurality of mask patterns as well as the first conductive layer exposed within the filling holes to expose the base substrate.

7. The method of claim 6, wherein while removing the first conductive layer exposed within the filling holes, a portion of the base substrate exposed within the filling holes is also removed, forming recesses that expose the active areas.

8. The method of claim 1, wherein forming the second conductive layer in the filling holes, with the doping concentration of the second conductive layer greater than the doping concentration of the first conductive layer, comprises:
depositing the second conductive layer in the filling holes, on the plurality of mask patterns, and on the first conductive layer, with the second conductive layer filling up the filling holes and covering the top surfaces of the plurality of mask pattern and a top surface of the first conductive layer;
wherein each one of the plurality of mask patterns comprises a support layer, a third conductive layer, and a first protective layer that are stacked up in sequence; after depositing the second conductive layer in the filling holes, on the plurality of mask patterns, and on the first conductive layer, with the second conductive layer filling up the filling holes and covering the top surfaces of the plurality of mask patterns and the top surface of the first conductive layer, the method further comprises:
etching the second conductive layer, the first conductive layer, and the first protective layer to expose the third conductive layer;
forming an initial bit line layer on the first conductive layer, the second conductive layer, and the third conductive layer; and
etching the initial bit line layer, the first conductive layer, the second conductive layer, and the third conductive layer, wherein the initial bit line layer forms a plurality of bit lines that are spaced apart and extend along the first direction, the first conductive layer forms a first contact layer, the second conductive layer forms a second contact layer, and the third conductive layer forms a connecting part; the first contact layer is connected on two opposing sides of each connecting part along the first direction and extends to the base substrate, and the second contact layer is filled between two adjacent first contact layers along the first direction.

9. The method of claim 1, wherein forming the plurality of mask patterns arranged in an array and spaced apart on the base substrate comprises:
forming a laminated structure on the base substrate;
forming a mask layer on the laminated structure, wherein the mask layer is provided with a preset pattern; and
etching the laminated structure by using the mask layer as a mask, with a remaining portion of the laminated structure forming the plurality of mask patterns.

10. The method of claim 9, wherein the preset pattern comprises a plurality of pattern units arranged in an array and spaced apart; the plurality of pattern units correspond to the end parts of the plurality of active areas, and the end parts of two of the plurality of active areas adjacent to each other along the first direction correspond to one of the plurality of pattern units; in any three adjacent rows of the plurality of pattern units, pattern units in a same row are arranged along the second direction, pattern units in adjacent rows are offset, and pattern units in alternate rows are oppositely arranged; a fourth distance between two of the plurality of pattern units adjacent to each other in a same row and a fifth distance between two of the plurality of pattern units opposite each other in alternate rows are both greater than a sixth distance between two of the plurality of pattern units adjacent to each other in adjacent rows;
the preset pattern is formed through at least one patterning process.

11. A semiconductor structure, comprising:
a base substrate, wherein the base substrate is provided with a plurality of active areas spaced apart from each other;
a plurality of mask patterns arranged in an array and spaced apart on the base substrate, wherein the plurality of mask patterns cover end parts of the plurality of active areas, and the end parts of two of the plurality of active areas adjacent to each other along a first direction share one of the plurality of mask patterns; in any three adjacent rows of the plurality of mask patterns, mask patterns in a same row are arranged along a second direction, mask patterns in adjacent rows are offset, and mask patterns in alternate rows are oppositely arranged; a first distance between two of the plurality of mask patterns adjacent to each other in a same row and a second distance between two of the plurality of mask patterns opposite each other in alternate rows are both greater than a third distance between two of the plurality of mask patterns adjacent to each other in adjacent rows; the second direction intersects with the first direction; and
bit line contact structures in contact with the plurality of active areas, each of the bit line contact structures comprising a first contact layer and a second contact layer, wherein the first contact layer is connected on two opposing sides of each one of the plurality of mask patterns along the first direction, and a thickness of the first contact layer is greater than one-half of the third distance and less than one-half of the second distance; the second contact layer is located between two first contact layers adjacent to each other along the first direction, and a doping concentration of the second contact layer is greater than a doping concentration of the first contact layers.

12. The semiconductor structure of claim 11, further comprising: a plurality of bit lines that are spaced apart and extend along the first direction, wherein each one of the plurality of bit lines is correspondingly in contact with a column of the bit line contact structures arranged along the first direction, and each one of the plurality of bit lines is correspondingly in contact with a column of the mask patterns opposite each other in alternate rows.

13. The semiconductor structure of claim 11, wherein a bottom surface of the first contact layer and a bottom surface of the second contact layer are both lower than a top surface of the base substrate, and the first contact layer and the second contact layer are both in contact with the active area.

14. The semiconductor structure of claim 13, wherein the bottom surface of the second contact layer is lower than the bottom surface of the first contact layer.

15. The semiconductor structure of claim 11, wherein the first contact layer comprises an undoped polysilicon layer, and the second contact layer comprises an N-type doped polysilicon layer.

16. The semiconductor structure of claim 11, wherein the plurality of mask patterns are arranged in a hexagonal layout, with a row of mask patterns between alternate rows of mask patterns located along a central axis between the two alternate rows of mask patterns, and the mask patterns at the central axis positions are located at a central position of four adjacent mask patterns in adjacent rows.

17. The semiconductor structure of claim 11, wherein each one of the plurality of mask patterns comprises a support layer and a connecting part that are stacked up in sequence.

18. The semiconductor structure of claim 17, wherein the support layer comprises a second protective layer disposed on the base substrate and a barrier layer disposed on the second protective layer.

19. The semiconductor structure of claim 17, wherein the first contact layer is connected on two opposing sides of each connecting part along the first direction, and top surfaces of the first contact layer, the second contact layer, and the connecting part are flush with each other.

20. The semiconductor structure of claim 19, wherein the plurality of bit lines are disposed on the top surfaces of the first contact layer, the second contact layer, and the connecting part, and each one of the plurality of bit lines comprises a metal layer and a cap layer disposed on the metal layer.
